(19) United States
(12) Patent Application Publication
(10) Pub. No.: US 2024/0319603 A1
(43) Pub. Date: Sep. 26, 2024

(54) EUV SENSITIVE METAL OXIDE MATERIAL AS UNDERLAYER FOR THIN CAR TO IMPROVE PATTERN TRANSFER

(71) Applicant: Applied Materials, Inc., Santa Clara, CA (US)

(72) Inventors: ZHENXING HAN, Sunnyvale, CA (US); MADHUR SACHAN, Belmont, CA (US); RUIYING HAO, San Jose, CA (US); NANCY FUNG, Livermore, CA (US); LIKUN WANG, Cupertino, CA (US); GABRIELA ALVA, Santa Clara, CA (US)

(21) Appl. No.: 18/581,290

(22) Filed: Feb. 19, 2024

Related U.S. Application Data
(60) Provisional application No. 63/466,897, filed on May 16, 2023.
(60) Provisional application No. 63/453,410, filed on Mar. 20, 2023.

(51) Int. Cl. G03F 7/16; G03F 7/004; G03F 7/20

(52) U.S. Cl. CPC G03F 7/162; G03F 7/0043; G03F 7/2002

(57) ABSTRACT

Embodiments disclosed herein include a method of patterning a substrate. In an embodiment, the method comprises depositing a metal-oxo layer over a substrate, and applying a chemically amplified resist (CAR) over the metal-oxo layer. In an embodiment, the method further comprises exposing the CAR, and developing the CAR to form a pattern in the CAR. In an embodiment, the method further comprises transferring the pattern into the metal-oxo layer, and transferring the pattern into the substrate.

### CROSS-REFERENCE TO RELATED APPLICATIONS

This application claims benefit of U.S. Patent Application No. 63/466,897, filed on May 16, 2023, and U.S. Patent Application No. 63/453,410, filed on Mar. 20, 2023, the entire contents of which are hereby incorporated by reference herein.

### BACKGROUND

### 1) Field

Embodiments of the present disclosure pertain to the field of semiconductor processing and, in particular, to a chemically amplified resist (CAR) that is provided over a metal oxide (i.e., metal-oxo) underlayer for improved pattern transfer.

### 2) Description of Related Art

Lithography has been used in the semiconductor industry for decades for creating 2D and 3D patterns in microelectronic devices. The lithography process involves spin-on deposition of a film (photoresist), irradiation of the film with a selected pattern by an energy source (exposure), and removal (develop) of exposed (positive tone) or non-exposed (negative tone) region of the film by dissolving in a solvent. A bake will be carried out to drive off remaining solvent.

The photoresist should be a radiation sensitive material and upon irradiation a chemical transformation occurs in the exposed part of the film which enables a change in solubility between exposed and non-exposed regions. Using this solubility change, either exposed or non-exposed regions of the photoresist are removed. Now the photoresist is developed and the pattern can be transferred to the underlying thin film or substrate by etching. After the pattern is transferred, the residual photoresist is removed and repeating this process many times can give 2D and 3D structures to be used in microelectronic devices.

Several properties are important in lithography processes. Such important properties include sensitivity, resolution, lower line-edge roughness (LER), etch resistance, and ability to form thinner layers. When the sensitivity is higher, the energy required to change the solubility of the as-deposited film is lower. This enables higher efficiency in the lithographic process. Resolution and LER determine how narrow features can be achieved by the lithographic process. Higher etch resistant materials are required for pattern transferring to form deep structures. Higher etch resistant materials also enable thinner films. Thinner films increase the efficiency of the lithographic process.

### SUMMARY

Embodiments disclosed herein include a method of patterning a substrate. In an embodiment, the method comprises depositing a metal-oxo layer over a substrate, and applying a chemically amplified resist (CAR) over the metal-oxo layer. In an embodiment, the method further comprises exposing the CAR, and developing the CAR to form a pattern in the CAR. In an embodiment, the method further comprises transferring the pattern into the metal-oxo layer, and transferring the pattern into the substrate.

Embodiments disclosed herein further comprise a photoresist stack. In an embodiment, the photoresist stack comprises an underlayer that is sensitive to extreme ultraviolet (EUV) radiation, and a chemically amplified resist (CAR) over the underlayer. In an embodiment, the CAR is sensitive to EUV radiation.

Embodiments disclosed herein further comprise a method of patterning a substrate, comprising providing an underlayer over the substrate, where the underlayer is sensitive to extreme ultraviolet (EUV) radiation, and disposing a chemically amplified resist (CAR) over the underlayer, where the CAR is applied with a spin coating process. In an embodiment, the method further comprises exposing and developing the CAR to form a pattern in the CAR, transferring the pattern into the underlayer, and transferring the pattern into the substrate.

### BRIEF DESCRIPTION OF THE DRAWINGS

FIG. 1 is a cross-sectional illustration of a substrate with a single chemically amplified resist (CAR) over the substrate.

FIG. 2 is a cross-sectional illustration of a substrate with a metal oxide (i.e., metal-oxo) underlayer and a CAR over the underlayer, in accordance with an embodiment.

FIG. 3A is a cross-sectional illustration of a substrate with a metal-oxo underlayer on the substrate, in accordance with an embodiment.

FIG. 3B is a cross-sectional illustration of the substrate after a CAR is applied over the metal-oxo underlayer, in accordance with an embodiment.

FIG. 3C is a cross-sectional illustration of the substrate after the CAR is patterned, in accordance with an embodiment.

FIG. 3D is a cross-sectional illustration of the substrate after the pattern in the CAR is transferred into the metal-oxo underlayer using a dry develop process, in accordance with an embodiment.

FIG. 3E is a cross-sectional illustration of the substrate after the pattern is transferred into the substrate, in accordance with an embodiment.

FIG. 4A is a cross-sectional illustration of a substrate with a metal-oxo underlayer and a CAR over the underlayer, in accordance with an embodiment.

FIG. 4B is a cross-sectional illustration of the substrate after the CAR and the metal-oxo underlayer are developed, in accordance with an embodiment.

FIG. 4C is a cross-sectional illustration of the substrate after the pattern is transferred into the substrate, in accordance with an embodiment.

FIG. 5 is a process flow diagram of a process for patterning a substrate using a metal-oxo underlayer and a CAR, in accordance with an embodiment.

FIG. 6 is a schematic illustration of a cluster tool that may be used in order to process a substrate with a metal-oxo underlayer and a CAR, in accordance with an embodiment.

FIG. 7 illustrates a block diagram of an exemplary computer system, in accordance with an embodiment of the present disclosure.

### DETAILED DESCRIPTION

A chemically amplified resist (CAR) that is provided over a metal oxide (i.e., metal-oxo) underlayer for improved pattern transfer is described herein. In the following description, numerous specific details are set forth, such as thermal vapor phase processes and material regimes for developing photoresist, in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

To provide context, photoresist systems used in extreme ultraviolet (EUV) lithography suffer from low efficiency. That is, existing photoresist material systems for EUV lithography require high dosages in order to provide the needed solubility switch that allows for developing the photoresist material. Chemically amplified resists (CARs) include chemistry that is sensitive to the EUV radiation.

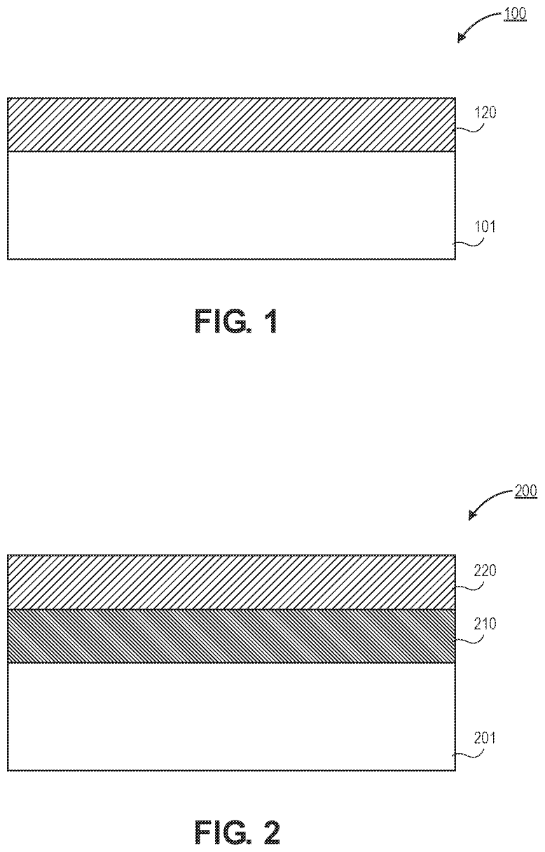

An example of a structure 100 with a standard CAR system is shown in FIG. 1. As shown, a CAR 120 may be deposited over the surface of a substrate 101. The substrate 101 may be any type of layer (or layers) that is to be patterned with an etching process. For example, the substrate 101 may comprise a semiconductor material (e.g., silicon), an oxide, a nitride, a metal, or the like. In an embodiment, the substrate 101 may also include hardmask materials (e.g., carbon containing hardmasks) provided above the layer to be patterned. Typically, the CAR 120 is applied with a spin coating process. That is, a solvent containing the CAR 120 is dispensed onto the substrate 101, and the substrate 101 is spun at high revolutions per minute (RPM) in order to distribute a thin layer of the CAR 120 over the surface of the substrate 101. Solvents and the like may be subsequently removed (or partially removed) using a baking process.

The chemical amplification concept of a CAR uses a photochemically-generated acid as a catalyst. The catalyst induces a cascade of chemical transformations in the resist film, providing a gain mechanism to fully convert exposed regions of the photoresist. The converted regions of the CAR are then etch selective to the unexposed regions. As such, a developing process can be used to remove the exposed regions leaving the unexposed regions intact, or to remove the unexposed regions leaving the exposed regions intact.

Traditionally, resist architectures may include thick resist material in order to provide the necessary etch resistance for pattern transfer into an underlying substrate. However, thicker resists can suffer pattern collapse when dense patterning (e.g., fine pitch structures) are necessary. Additionally, thicker resist layers require larger dosages of EUV radiation in order to produce a solubility switch through the entire thickness of the resist. These issues can lead to increased LWR and, ultimately, poor pattern transfer performance.

In other instances, organic-inorganic hybrid materials (e.g., metal-oxo materials systems) have been proposed as a material system for EUV lithography due to the increased sensitivity to EUV radiation. Such material systems typically comprise a metal (e.g., Sn, Hf, Zr, etc.), oxygen, and carbon. For example, the metal element may be bonded to butyl groups, hydroxyl groups, phenyl groups, or the like. In a metal-oxo photoresist system, exposure to EUV radiation results in crosslinking and the removal of carbon. The difference in the carbon percentage between the exposed regions and the unexposed regions is used as the solubility switch during developing. Particularly, the unexposed regions with the higher carbon content are preferentially etched by the developer solution in a negative tone develop. Though, it is to be appreciated that a positive tone develop may also be used in some embodiments.

Accordingly, embodiments disclosed herein may use a combination of a CAR material with a metal-oxo underlayer in order to leverage the benefits of each type of resist system. The combination of a thin CAR with a metal-oxo underlayer may provide improved LWR and overall pattern transfer improvements. In an embodiment, the metal-oxo underlayer provides improved resistance to the etching chemistry, and therefore sets the LWR for the patterning. Additionally, the presence of the metal-oxo underlayer may aid in dose reduction of the resist system, and provide improved adhesion properties.

Previously, the combination of a CAR system with an metal-oxo system was not attempted because the solvents used for CAR deposition typically dissolve the metal-oxo film. However, with post deposition treatments to the metal-oxo layer, resistance to the solvent can be provided. For example, treatments may include thermal treatment, ultraviolet (UV) radiation treatments, or chemical treatments. Such treatments may alter the cross-linking characteristics of the metal-oxo layer to render the surface of the metal-oxo layer more resistant to the solvent of the CAR.

Further, deposition parameters of the metal-oxo film can be modified to improve resistance as well. This is because the metal-oxo film may be deposited with a dry deposition process (e.g., atomic layer deposition (ALD), chemical vapor deposition (CVD), physical vapor deposition (PVD), etc.) which allows for tuning properties of the resist through a thickness of the resist. In additional embodiments, the combination of a metal-oxo system and a CAR system may also improve bonding to the underlying substrate. For example, the metal-oxo material may have organic ligands that are prone to adhering to CAR type materials that have —CH₃ terminations. As such, adhesion challenges for existing CAR systems are mitigated.

As used herein, reference to a metal-oxo underlayer and a CAR photoresist are provided as one example of suitable materials. However, it is to be appreciated that any material that is sensitive to EUV radiation may be used as the underlayer. Similarly, any EUV sensitive material may be used as the photoresist over the underlayer. That is, the photoresist need not be a CAR in some embodiments. In a particular embodiment, the underlayer is a metal-oxo underlayer, and the overlying photoresist is an EUV sensitive photoresist material. Both the underlayer and the photoresist may be developed with a dry develop process similar to embodiments described herein.

Referring now to FIG. 2, a cross-sectional illustration of a structure 200 with a hybrid resist system is shown, in accordance with an embodiment. In an embodiment, the structure 200 may include a substrate 201. The substrate 201 may be any type of layer (or layers) that is to be patterned with an etching process. For example, the substrate 201 may comprise a semiconductor material (e.g., silicon), an oxide, a nitride, a metal, or the like. In an embodiment, the substrate 201 may also include hardmask materials (e.g., carbon containing hardmasks) provided above the layer to be patterned.

In an embodiment, a first photosensitive resist layer 210 may be provided over the substrate 201, and a second photosensitive resist layer 220 may be provided over the first photosensitive resist layer 210. The first resist layer 210 may be a different class of resist than the second resist layer 220. For example, and as used throughout the rest of this disclosure, the first resist layer 210 may be a metal-oxo resist 210, and the second resist layer 220 may be a CAR 220. In an embodiment, the thickness of the metal-oxo resist 210 may be greater than a thickness of the CAR 220. Though, in other embodiments, the metal-oxo resist 210 and the CAR 220 may have similar thicknesses, or the CAR 220 may be thicker than the metal-oxo resist 210. More generally, a total thickness of the CAR 220 and metal-oxo resist 210 may be thinner than the thickness required of a CAR 220 without a metal-oxo resist 210 underlayer.

In an embodiment, the metal-oxo resist 210 may be applied with any suitable deposition process. In one embodiment, the metal-oxo resist 210 may be applied with a spin coating process. In another embodiment, the metal-oxo resist 210 may be applied with a dry deposition process. For example, ALD, CVD, or PVD processes may be used to deposit the metal-oxo resist 210. Dry deposition processes may allow for enhanced tuning of the properties of the metal-oxo resist 210. Modulation of various deposition parameters, (e.g., temperature, gas flow rates, pressure, etc.) can be used to provide a metal-oxo resist 210 that has non-uniform properties through a thickness of the metal-oxo resist 210. For example, a bottom of the metal-oxo resist 210 may be tuned for adhesion strength improvements, and an upper region of the metal-oxo resist 210 may be tuned for dose improvements, improvements in adhesion properties to the CAR 220, or etch resistance. Additionally, the metal-oxo resist 210 may be treated after deposition is completed. For example, thermal treatments, UV treatments, or chemical treatments may be used in order to improve performance of the hybrid resist system shown in structure 200.

In an embodiment, the metal-oxo resist 210 may have any suitable formulation. In one embodiment, the metal component may comprise tin. Though, other metal elements may be used instead of, or in combination with tin. The organic ligands used may also be any suitable ligand, such as those described in greater detail above. In an embodiment, the composition of the metal-oxo resist 210 may also be non-uniform through a thickness of the metal-oxo resist 210. Such embodiments may be enabled through the use of dry deposition processes.

After the metal-oxo resist 210 is deposited, the CAR 220 may be applied. In an embodiment, the CAR 220 may be applied with a typical spin coating process. As described above, the treatment of the metal-oxo resist 210 may protect the metal-oxo resist 210 from the negative impacts of the solvent used to deposit the CAR 220. That is, the CAR 220 may be applied as is, (i.e., without any formulation changes) while remaining compatible with the metal-oxo resist 210.

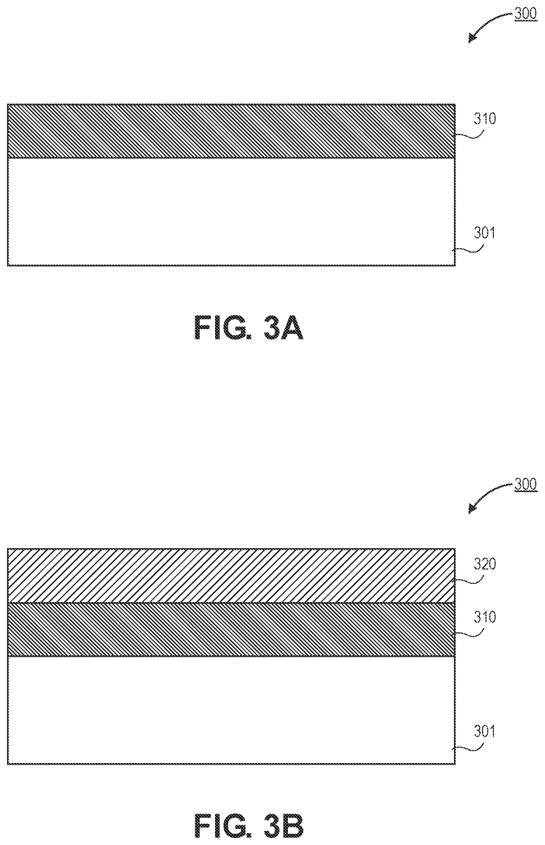

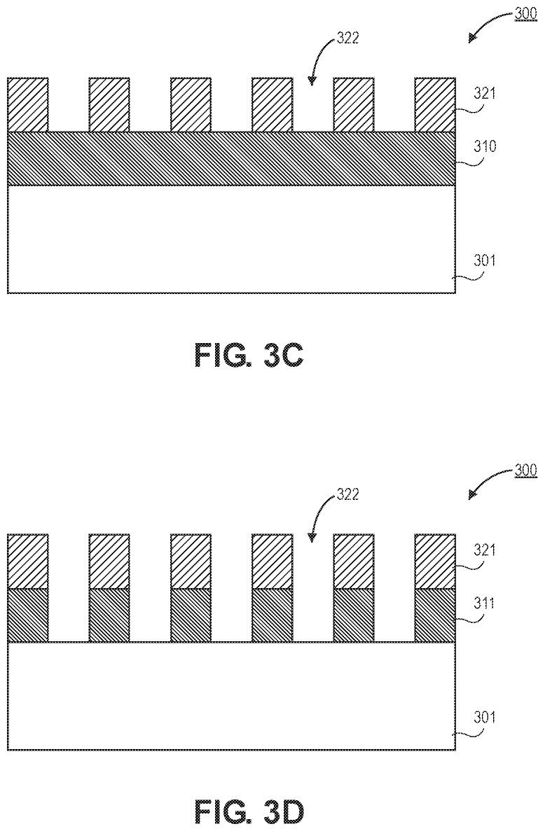

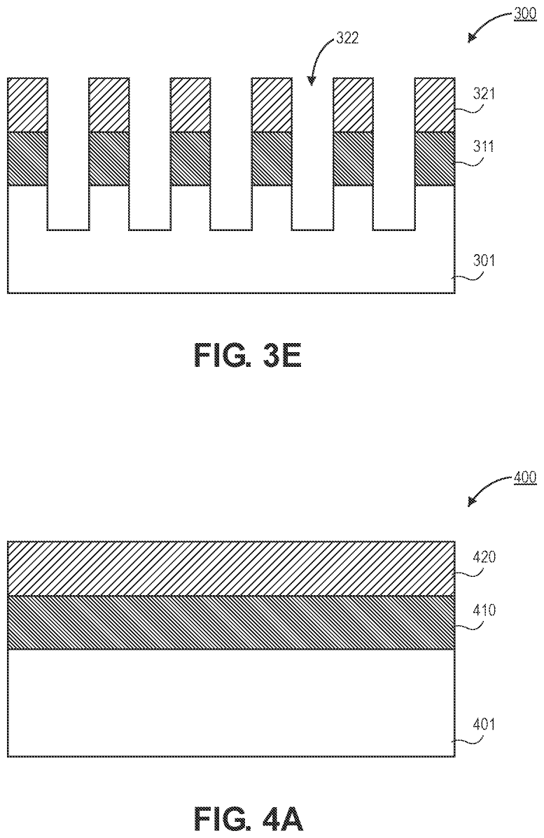

Referring now to FIGS. 3A-3E, a series of cross-sectional illustrations depicting a process and structure 300 for patterning a substrate is shown. In an embodiment, the process shown in FIGS. 3A-3E may utilize a dry develop process for the metal-oxo layer 310.

Referring now to FIG. 3A, a cross-sectional illustration of a structure 300 with a substrate 301 and a metal-oxo resist 310 is shown, in accordance with an embodiment. In an embodiment, the substrate 301 may be any suitable substrate that is to be patterned with a hybrid resist system. While shown as a single layer, it is to be appreciated that the substrate 301 may include multiple layers, one or more of which may be hardmask layers.

In an embodiment, the metal-oxo resist 310 may be applied over a surface of the substrate 301. In one embodiment, the metal-oxo resist 310 may be applied with a spin coating process. In other embodiments, a dry deposition process (e.g., ALD, CVD, PVD, etc.) may be used to deposit the metal-oxo resist 310 onto the substrate 301. A dry deposition process may provide more flexibility in the design of the metal-oxo resist 310. For example, deposition parameters, such as temperature, pressure, gas flow rates, etc. may be modulated in order to tune the metal-oxo resist 310 through a thickness of the metal-oxo resist 310. Additionally, a dry deposition process may be used to modulate a composition through the thickness of the metal-oxo resist 310. For example, different metal atoms may be provided at different thicknesses. In one embodiment, the metal-oxo resist 310 may comprise tin or any other suitable metal centers. The ligands may also be modulated through a thickness of the metal-oxo resist 310.

In an embodiment, the metal-oxo resist 310 may be subject to a treatment after deposition on the substrate 301. The treatment (or treatments) may be used in order to enhance compatibility with a subsequently deposited CAR. For example, the treatment may alter the cross-linking percentage in order to resist dissolution by a solvent used to deposit the CAR. In one embodiment, a thermal treatment is applied to the metal-oxo resist 310. A thermal treatment may include exposing the metal-oxo resist 310 to an elevated temperature for a given duration of time. For example, temperatures between 50 degrees Celsius and 250 degrees Celsius may be used, and the duration may be between one second and an hour or longer. In another embodiment, the treatment may include a UV treatment. The UV treatment may be implemented in any suitable atmosphere. For example, an atmosphere comprising one or more of nitrogen, oxygen, and argon may be used. In yet another embodiment, the treatment may include a chemical treatment. A chemical treatment may be used to change a polarity of the surface. One example of a suitable chemical treatment is application of hexamethyldisilane (HMDS).

Referring now to FIG. 3B, a cross-sectional illustration of the structure 300 after a CAR 320 is applied is shown, in accordance with an embodiment. In an embodiment, the CAR 320 may be applied with a spin coating process. However, due to the treatment of the metal-oxo resist 310, the solvent used for the spin coating does not negatively impact the metal-oxo resist 310. This allows for existing CARs 320 to be used without requiring reformulation.

Referring now to FIG. 3C, a cross-sectional illustration of the structure 300 after the CAR 320 is exposed and developed is shown, in accordance with an embodiment. In an embodiment, the CAR 320 may be exposed with EUV radiation. The EUV radiation results in a solubility switch in the CAR 320 that can subsequently be developed to form a patterned CAR 321. For example, openings 322 may be provided through a thickness of the patterned CAR 321. While not developed at this point, the underlying metal-oxo resist 310 may also be exposed with the exposure process used to pattern the patterned CAR 321. That is, a latent image of the pattern may be provided in the metal-oxo resist 310. The CAR 321 may be developed with a wet developing chemistry (e.g., a wet etch) or a dry etch.

Referring now to FIG. 3D, a cross-sectional illustration of the structure 300 after the metal-oxo resist 310 is patterned is shown, in accordance with an embodiment. In the particular embodiment shown in FIG. 3D, the metal-oxo resist 310 may be developed with a dry develop process. For example, etchants such as, but not limited to HCl, HBr, HI, and the like may be used in a dry etching environment to form the patterned metal-oxo resist 311. The etchants used to develop the metal-oxo resist 310 may have little impact (if any) on the patterned CAR 321. Additionally, the existing pattern of the patterned CAR 321 may aid in the developing of the underlying metal-oxo resist 310 by serving as an etchant mask. This allows for the metal-oxo resist 310 to have a lower necessary dose in order to enable good pattern transfer. In an embodiment, the dry develop process to form the patterned metal-oxo resist 311 may also be a thermal etching process. For example, a temperature of the structure 301 during the etch may be between −100 degrees Celsius and 350 degrees Celsius. The thermal process may also function as a post develop bake operation for the overlying patterned CAR 321.

Referring now to FIG. 3E, a cross-sectional illustration of the structure 300 after the pattern is transferred into the underlying substrate 301 is shown, in accordance with an embodiment. As shown, the openings 322 may be transferred into the substrate 301. The pattern transfer process may use any suitable etching process (e.g., wet etch or dry etch) that is selective to the substrate 301 over the patterned resist layers 311 and 321. In an embodiment, the resistance of the patterned metal-oxo resist 311 to the etching chemistry may be higher than the resistance of the patterned CAR 321 to the etching chemistry. However, since the patterned metal-oxo resist 311 remains, the LWR and other pattern transfer properties may be superior to embodiments with just a thin CAR alone.

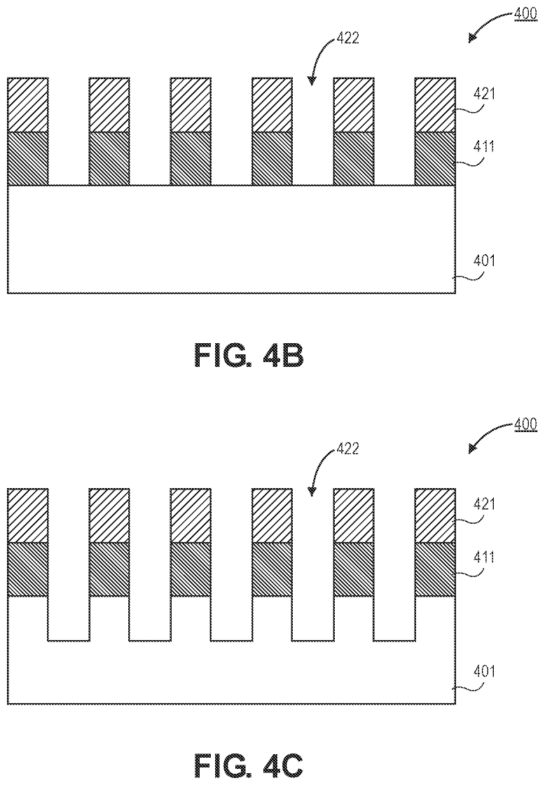

Referring now to FIGS. 4A-4C, a structure 400 with an alternative hybrid resist and patterning process is shown, in accordance with an embodiment.

Referring now to FIG. 4A, a cross-sectional illustration of a structure 400 with a substrate 401 and a metal-oxo resist 410 over the substrate 401 is shown, in accordance with an embodiment. In an embodiment, a CAR 420 may be applied over the metal-oxo resist 410. In an embodiment, the structure 400 may be similar to the structure 300 shown in FIG. 3A. That is, the metal-oxo resist 410 may be deposited with a dry deposition process in order to provide enhanced capabilities to tune the metal-oxo resist 410. The metal-oxo resist 410 may also be treated (e.g., with a thermal treatment, a UV treatment, and/or a chemical treatment). Thereafter, the CAR 420 is applied.

In an embodiment, the CAR 420 may include any suitable CAR material. The CAR 420 may be applied with a spin coating process. Since the metal-oxo resist 410 has been treated, the solvent used to dispense the CAR 420 may not negatively impact the performance or structure of the underlying metal-oxo resist 410. In an embodiment, the CAR 420 may have a thickness that is less than a thickness of the metal-oxo resist 410. Though, a thicker CAR 420 may also be used in some embodiments. More generally, a combined thickness of the CAR 420 and metal-oxo resist 410 may be less than a thickness of a CAR 420 when no metal-oxo resist 410 underlayer is provided.

Referring now to FIG. 4B, a cross-sectional illustration of the structure 400 after a pattern 422 is formed into the CAR 420 and the metal-oxo resist 410 to form a patterned CAR 421 and a patterned metal-oxo resist 411. In contrast to the embodiment described above with respect to FIGS. 3A-3E, the developing process may be done with a single developing solution. For example, an EUV exposure may be made on the structure 400, and the exposure is followed by a single developing process that removes portions of both the CAR 420 and the underlying metal-oxo resist 410. In an embodiment, the developer may be a wet etching chemistry or a dry etching chemistry.

Referring now to FIG. 4C a cross-sectional illustration of the structure 400 after the pattern is transferred into the underlying substrate 401 is shown, in accordance with an embodiment. As shown, the openings of pattern 422 may be transferred into the substrate 401. The pattern transfer process may use any suitable etching process (e.g., wet etch or dry etch) that is selective to the substrate 401 over the patterned resist layers 411 and 421. In an embodiment, the resistance of the patterned metal-oxo resist 411 to the etching chemistry may be higher than the resistance of the patterned CAR 421 to the etching chemistry. However, since the patterned metal-oxo resist 411 remains, the LWR and other pattern transfer properties may be superior to embodiments with just a thin CAR alone.

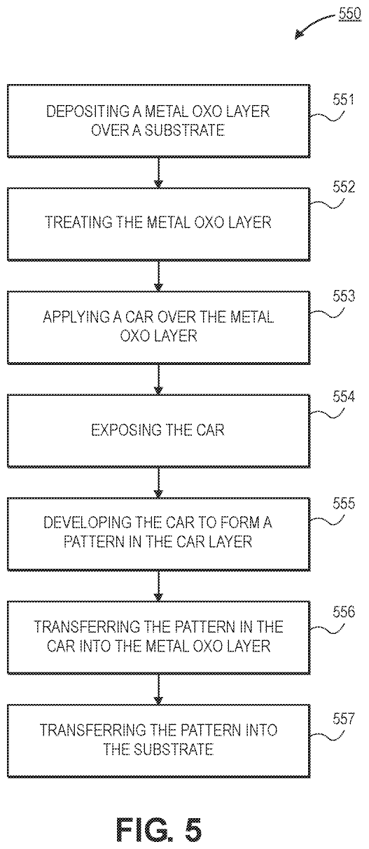

Referring now to FIG. 5, a process flow diagram depicting a process 550 for patterning a substrate using a hybrid resist stack is shown, in accordance with an embodiment. In an embodiment, the process 550 may be similar to either of the processing flows depicted above in FIGS. 3A-3E or FIGS. 4A-4C.

In an embodiment, the process 550 may begin with depositing a metal-oxo resist layer over a substrate. The metal-oxo resist may be deposited with either a wet (e.g., spin coating) or dry (e.g., ALD, CVD, PVD, etc.) deposition process. In the case of a dry deposition process, the processing parameters may be modulated in order to provide a metal-oxo resist with non-uniform thickness composition and/or non-uniform material properties (e.g., adhesion strength, dose, etc.). In an embodiment, the substrate may be any material that is to be patterned with the hybrid resist stack, which may include hardmask layers. While a metal-oxo resist layer is described in detail with respect to process 550. It is to be appreciated that any EUV sensitive material may be used as the underlayer in process 550.

In an embodiment, the process 550 may continue with operation 552, which comprises treating the metal-oxo resist. In an embodiment, the treatment may be implemented after the metal-oxo resist is deposited. The treatment may include one or more of a thermal treatment, a UV treatment, or a chemical treatment. Details of such treatments may be similar to those described in greater detail above. In an embodiment, the treatment process may modify the cross-linking of the metal-oxo resist in order to provide enhanced protection from the solvent of a subsequently deposited CAR. In an embodiment, the treatment may also modify surface chemistry, polarity, and the like. For example, the surface treatment may improve the adhesion to the subsequently deposited CAR.

In an embodiment, the process 550 may continue with operation 553, which comprises applying a CAR over the metal-oxo resist. In an embodiment, the CAR may be applied with a spin coating process or the like. In some embodiments, a thickness of the CAR is thinner than a thickness of the metal-oxo resist. Though, in other embodiments, the metal-oxo resist may be thinner, thicker, or the same thickness as the CAR. More generally, the combined thickness of the CAR and the metal-oxo resist may be thinner than when only a CAR is used.

While a CAR is provided as one example of a photoresist layer in the process 550, embodiments are not limited to such material systems. More generally, operation 553 may be used to deposit any EUV sensitive resist material over the metal-oxo resist. In some embodiments, the photoresist layer may be another metal-oxo material or any other EUV sensitive material.

In an embodiment, the process 550 may continue with operation 554, which comprises exposing the CAR with EUV radiation. In an embodiment, the EUV radiation may provide a latent image in the CAR. For example, regions of the CAR exposed to EUV radiation undergo a solubility switch. In an embodiment, the exposure used to expose the CAR may also result in exposure of the underlying metal-oxo resist. That is, a latent image from a solubility switch may also be generated in the metal-oxo resist.

In an embodiment, the process 550 may continue with operation 555, which comprises developing the CAR to form a pattern in the CAR layer. In an embodiment, the developing may be implemented with a wet etching chemistry. In some embodiments, the developer solution only develops the CAR, leaving the metal-oxo resist unaltered. The CAR may also be developed with a dry developing process, such as a thermal dry develop.

In an embodiment, the process 550 may continue with operation 556, which comprises developing the metal-oxo resist to form the pattern in the metal-oxo resist. In some embodiments, the developing of the metal-oxo resist may be a dry develop process, such as a thermal develop. In other embodiments, the developing solution used to develop the CAR may also be used to develop the metal-oxo resist.

In an embodiment, the process 550 may continue with operation 557, which comprises transferring the pattern into the substrate. The pattern of the resist layers may be transferred into the substrate using an etching process, such as a wet etching process or a dry etching process.

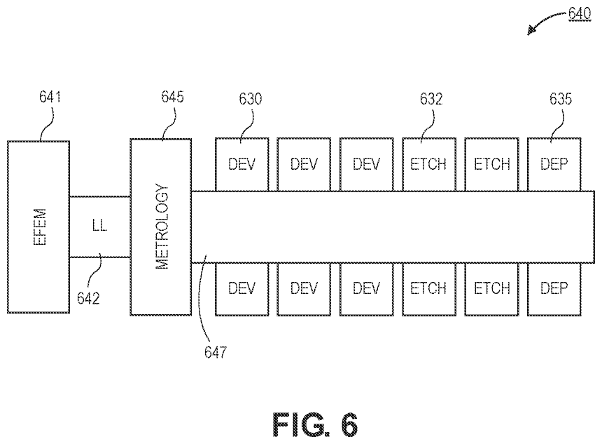

In the embodiments described in greater detail above, the tools used to implement the various processing operations are omitted. More generally, it is to be appreciated that individual processing tools may be used to execute each of the various processing operations. However, in other embodiments, two or more of the individual processing operations may be implemented in a single cluster tool. An example of one such cluster tool is shown in FIG. 6.

Referring now to FIG. 6, a plan view illustration of a cluster tool 600 is shown, in accordance with an embodiment. In an embodiment, the cluster tool 600 may comprise an equipment front end module (EFEM) 621. The EFEM 621 may receive front opening unified pods (FOUPs), cassettes, or the like as an entry point for substrates into the cluster tool 600. The substrates that are processed in the cluster tool 600 may include wafers (e.g., silicon wafers, or other semiconductor wafers) with any standard form factor, (e.g., 200 mm, 300 mm, 450 mm, etc.). In an embodiment, the EFEM 621 may be coupled to the rest of the cluster tool 600 through a load lock 622. The load lock 622 may separate an atmospheric condition in the EFEM from a vacuum condition in the rest of the cluster tool 600. Though, in some embodiments, the EFEM may also be held at a sub-atmospheric pressure (e.g., a higher pressure than on the other side of the load lock 622, but lower than atmospheric pressure).

In an embodiment, a metrology tool 625 may be provided after the load lock 622. The metrology tool 625 may be a scatterometry tool or any other metrology tool useful for after develop inspection (ADI) or after etch inspection (AEI) applications. In an embodiment, the metrology tool 625 may be communicatively coupled with a transfer chamber 627. The transfer chamber 627 may include robotic arms, tracks, or any suitable architecture for transporting the substrates between the metrology tool 625 and the remainder of the cluster tool 600.

In an embodiment, one or more develop chambers 610 and one or more etch chambers 612 may be coupled to the transfer chamber 627. For example, six develop chambers 610 and four etch chambers 612 are provided in the cluster tool 600. One or more deposition chambers 615 may also be provided in the cluster tool 600. The chambers 610, 612, and 615 may be provided on two sides of the transfer chamber 627 in order to optimize space savings. In an embodiment, the develop chambers 610 may be dry develop chambers. A plasma source may be used in conjunction with the develop chambers 610 in order to develop the resist layers without any wet chemistries. Additionally, the etch chambers 612 may be dry etching chambers 612 that use plasma to etch the substrate through the resist layer. The deposition chambers 615 may be dry deposition chambers (e.g., ALD, CVD, etc.) that are used to deposit photoresist layers. One or more of the deposition chamber 615 may also include a spin coating chamber.

In an embodiment, the substrate may enter the EFEM, pass through the load lock 622 and the metrology tool 625 and be delivered to one of deposition chambers 615. At one or more of the deposition chambers 615 a hybrid resist system including a metal-oxo resist and a CAR is applied. In an embodiment, the hybrid resist and substrate may be delivered to an exposure tool (which may be a different tool than the cluster tool 600). After developing, the substrate may be delivered to the metrology tool 625 for ADI. After ADI, the substrate may be delivered to one of the etch chambers 612 through the transfer chamber 627. There, the substrate may be etched through the developed resist layer. The substrate may then be transferred back to the metrology tool 625 for AEI. Accordingly, the operations of resist development, ADI, substrate etching, and AEI may occur within a single cluster tool 600 without needing to leave a vacuum environment.

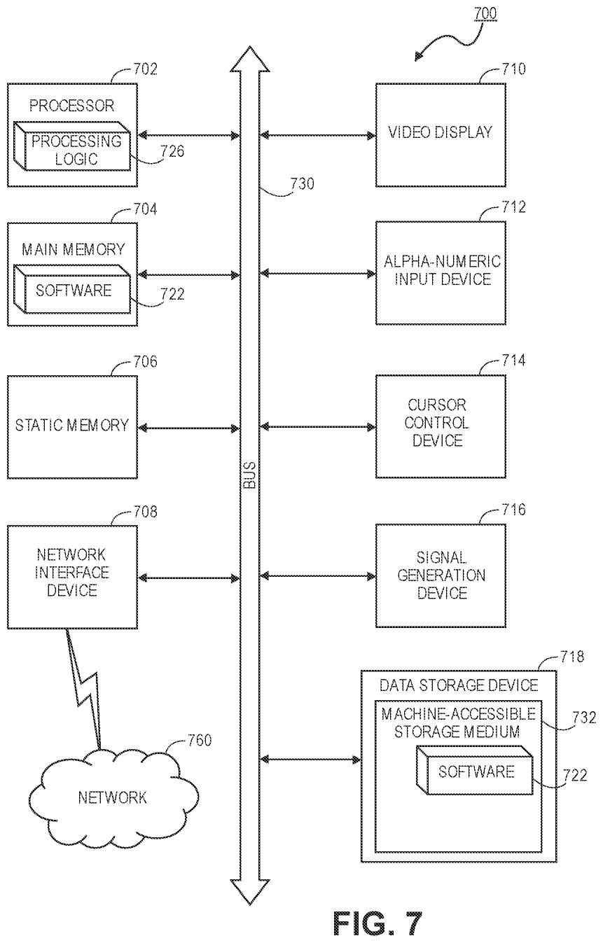

FIG. 7 illustrates a diagrammatic representation of a machine in the exemplary form of a computer system 700 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 700 includes a processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), MRAM, etc.), and a secondary memory 718 (e.g., a data storage device), which communicate with each other via a bus 730.

Processor 702 represents one or more general-purpose processing devices such as a microprocessor, central processing unit, or the like. More particularly, the processor 702 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 702 may also be one or more special-purpose processing devices such as an application specific integrated circuit (ASIC), a field programmable gate array (FPGA), a digital signal processor (DSP), network processor, or the like. Processor 702 is configured to execute the processing logic 726 for performing the operations described herein.

The computer system 700 may further include a network interface device 708. The computer system 700 also may include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium (or more specifically a computer-readable storage medium) 732 on which is stored one or more sets of instructions (e.g., software 722) embodying any one or more of the methodologies or functions described herein. The software 722 may also reside, completely or at least partially, within the main memory 704 and/or within the processor 702 during execution thereof by the computer system 700, the main memory 704 and the processor 702 also constituting machine-readable storage media. The software 722 may further be transmitted or received over a network 760 via the network interface device 708.

While the machine-accessible storage medium 732 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, and optical and magnetic media.

In accordance with an embodiment of the present disclosure, a machine-accessible storage medium has instructions stored thereon which cause a data processing system to perform a method of forming a hybrid resist system with a metal-oxo underlayer and a CAR, exposing the hybrid resist system, developing the hybrid resist system, and etching the underlying substrate. The process may be implemented at least in part with a cluster tool. The cluster tool may include a metrology tool, a develop chamber, a deposition chamber, and an etch chamber. In an embodiment, the methods disclosed herein allow for improved etching performance compared to conventional methods.

Thus, methods for processing substrates using a hybrid resist system with a metal-oxo underlayer and a CAR are described. In an embodiment, the substrate with the hybrid resist system may be processed in a cluster tool with a metrology tool, a dry develop chamber, a deposition chamber, and an etch chamber.

What is claimed is:

1. A method of patterning a substrate, comprising:
depositing an underlayer over a substrate;
applying an extreme ultra violet (EUV) sensitive resist over the underlayer;
exposing the substrate;
developing the EUV sensitive resist to form a pattern in the EUV sensitive resist;
transferring the pattern into the underlayer; and
transferring the pattern into the substrate.

2. The method of claim 1, further comprising:
treating the underlayer with a treatment process before the EUV sensitive resist is applied.

3. The method of claim 2, wherein the treatment process comprises a thermal treatment.

4. The method of claim 3, wherein the thermal treatment is at a temperature between approximately 70 degrees Celsius and approximately 250 degrees Celsius.

5. The method of claim 2, wherein the treatment process comprises an ultraviolet (UV) radiation treatment.

6. The method of claim 5, wherein the UV radiation treatment is done in an atmosphere comprising one or more of nitrogen, oxygen, and argon.

7. The method of claim 2, wherein the treatment comprises a chemical treatment.

8. The method of claim 7, wherein the chemical treatment comprises hexamethyldisilane (HMDS).

9. The method of claim 1, wherein transferring the pattern into the underlayer is done with a dry develop process.

10. The method of claim 1, wherein developing the EUV sensitive resist to form a pattern in the EUV sensitive resist and transferring the pattern into the underlayer is done with a single wet develop process or dry develop process.

11. The method of claim 1, wherein a combined thickness of the EUV sensitive resist and the underlayer is less than a required thickness of a EUV sensitive resist alone.

12. The method of claim 1, wherein two or more of the processes are implemented in a single cluster tool.

13. The method of claim 1, wherein the substrate is a hardmask layer.

14. A photoresist stack, comprising:
an underlayer, wherein the underlayer is sensitive to extreme ultraviolet (EUV) radiation; and
an EUV sensitive resist over the underlayer.

15. The photoresist stack of claim 14, wherein the underlayer comprises a metal-oxo material.

16. The photoresist stack of claim 15, wherein the metal-oxo material comprises tin.

17. A method of patterning a substrate, comprising:
providing an underlayer over the substrate, wherein the underlayer is sensitive to extreme ultraviolet (EUV) radiation;
disposing a photoresist over the underlayer, wherein the photoresist is sensitive to EUV radiation, and wherein the photoresist is applied with a spin coating process;
exposing the substrate to EUV radiation and developing the photoresist to form a pattern in the photoresist;
transferring the pattern into the underlayer; and
transferring the pattern into the substrate.

18. The method of claim 17, wherein the underlayer is treated before the photoresist is applied, wherein the treatment comprises a thermal treatment, an ultraviolet (UV) radiation treatment, or a chemical treatment.

19. The method of claim 17, wherein transferring the pattern into the underlayer is done with a dry developing process.

20. The method of claim 17, wherein two or more of the processes are implemented in a single cluster tool.
